(19) United States
(12) Patent Application Publication
(10) Pub. No.: US 2015/0074161 A1
(43) Pub. Date: Mar. 12, 2015

(54) LEAST MEAN SQUARE METHOD FOR ESTIMATION IN SPARSE ADAPTIVE NETWORKS

(71) Applicant: KING FAHD UNIVERSITY OF PETROLEUM AND MINERALS, DHAHRAN (SA)

(72) Inventors: MUHAMMAD OMER BIN SAEED, DHAHRAN (SA); ASRAR UL HAQ SHEIKH, DHAHRAN (SA)

(73) Assignee: KING FAHD UNIVERSITY OF PETROLEUM AND MINERALS, DHAHRAN (SA)

(21) Appl. No.: 14/022,176

(22) Filed: Sep. 9, 2013

(51) Int. Cl. H03H 21/00

(52) U.S. Cl. CPC H03H 21/0012
USPC 708/322

(57) ABSTRACT

The least mean square method for estimation in sparse adaptive networks is based on the Reweighted Zero Attracting Least Mean Square (RZA-LMS) algorithm, providing estimation for each node in the adaptive network. The extra penalty term of the RZA-LMS algorithm is then integrated into the Incremental LMS (ILMS) algorithm. Alternatively, the extra penalty term of the RZA-LMS algorithm may be integrated into the Diffusion LMS (DLMS) algorithm.

### BACKGROUND OF THE INVENTION

1. Field of the Invention

The present invention relates generally to adaptive networks, such as sensor networks, and particularly to a least mean square method for estimation in sparse adaptive networks.

2. Description of the Related Art

Least mean squares (LMS) algorithms are a class of adaptive filters used to mimic a desired filter by finding the filter coefficients that relate to producing the least mean squares of the error signal (i.e., the difference between the desired and the actual signal). The LMS algorithm is a stochastic gradient descent method, in that the filter is only adapted based on the error at the current time.

In an adaptive network having N nodes, where the network has a predefined topology, for each node k, the number of neighbors is given by Nₖ, including the node k itself. In the normalized (NLMS) algorithm, at each iteration i, the output of the system at each node is given by dₖ(i)=uₖ(i)w⁰+vₖ(i), where uₖ(i) is a known regressor row vector of length M, w⁰ is an unknown column vector of length M, and vₖ(i) represents noise. The variable i is a time index. The output and regressor data are used to produce an estimate of the unknown vector, given by wₖ(i). If the estimate at any time instant i of w⁰ is denoted by the vector wₖ(i) then the estimation error is given by eₖ(i)=dₖ(i)−uₖ(i)wₖ(i). The NLMS algorithm is defined by the calculation of wₖ(i) through the iteration

$${w}_{k} ( i + 1 ) = {w}_{k} ( i ) + {μ}_{k} {e}_{k} ( i ) \frac{{u}_{k}^{T} ( i )}{{‖ {u}_{k} ( i ) ‖}^{2}} ,$$

where the superscript “T” represents the transpose of uₖ(i) and “∥ ∥” represents the Euclidean norm. Further, μₖ represents a step size, defined in the range 0<μₖ<2.

The use of the l₀-norm in compressed sensing problems has been shown to perform better than the l₂-norm in sparse environments. Since the use of the l₀-norm is not feasible, an approximation can be used instead (such as the l₁-norm). The Reweighted Zero Attracting LMS (RZA-LMS) algorithm is based on an approximation of the l₀-norm. In the RZA-LMS algorithm, the output vector wₖ(i) for each node k is given as:

$${w}_{k} ( i + 1 ) = {w}_{k} ( i ) + {μ}_{k} {e}_{k} ( i ) {u}_{k}^{T} ( i ) - ρ \frac{sgn ( {w}_{k} ( i ) )}{1 + {o}^{′} \vert {w}_{k} ( i ) \vert} ,$$

where ρ and o′ are unitless, positive control parameters and “sgn” represents the signum (or “sign”) function. The RZA-LMS algorithm performs better than the standard LMS algorithm in sparse systems.

In the Incremental LMS (ILMS) algorithm, an output vector w(i) is introduced and is used as an intermediate vector for calculation of the estimate of the unknown vector w⁰, the intermediate estimate at each node being denoted as ψₖ(i). The ILMS algorithm is an iterative algorithm over the time index i. The ILMS algorithm includes the following steps: (a) establishing an adaptive network having N nodes, where N is an integer greater than one, and then establishing a Hamiltonian cycle among the nodes so that each node is connected to two neighboring nodes, one from which it receives data and one to which it transmits data; (b) establishing an integer i and initially setting i=1; (c) establishing an estimate of an output vector for each node k at iteration i, ψₖ(i), and an output vector at iteration i, w(i), such that ψ₀(i)=w(i−1); (d) calculating an output of the adaptive network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer; (e) calculating an error value eₖ(i) at each node k as eₖ=dₖ−uₖ(i)ψₖ₋₁(i); (f) calculating the estimate of the output vector ψₖ(i) for each node k as ψₖ(i)=ψₖ₋₁(i)+μₖuₖ^{T}eₖ(i), where μₖ is a constant step size; (g) if k=N, then setting w(i)=ψ_{N}(i); (h) if eₖ(i) is greater than a selected error threshold, then setting i=i+1 and returning to step (d); otherwise, (i) storing the set of output vectors w(i).

In the Diffusion LMS (DLMS) algorithm, the output vector w(i) is replaced in the calculation of the estimate of the unknown vector w⁰ with an output vector defined at each node k, wₖ(i). The DLMS algorithm is also an iterative algorithm over the time index i. The DLMS algorithm includes the following steps: (a) establishing an adaptive network having N nodes, where N is an integer greater than one, and for each node k, a number of neighbors of node k is given by Nₖ, including the node k, where k is an integer between one and N; (b) establishing an integer i and initially setting i=1; (c) establishing an estimate of an output vector for each node k at iteration i, ψₖ(i), such that

$${ψ}_{k} ( i ) = {\sum }_{l ∈ {N}_{k}}^{ } {c}_{lk} {w}_{l} ( i - 1 ) ,$$

where cₗₖ represents a weight of the estimate shared by node l for node k; (d) calculating an output of the adaptive network at each node k as dₖ=uₖ(i)w⁰+vₖ(i), where uₖ(i) represents a known regressor row vector of length M, w⁰ represents an unknown column vector of length M and vₖ(i) represents noise in the adaptive network, where M is an integer; (e) calculating an error value eₖ(i) at each node k as eₖ(i)=dₖ(i)−uₖ(i)ψₖ(i); (f) calculating the estimate of the output vector ψₖ(i) for each node k as ψₖ(i)=ψₖ(i)+μₖuₖ^{T}eₖ(i), where μₖ is a constant step size; (g) if eₖ(i) is greater than a selected error threshold, then setting i=i+1 and returning to step (d); otherwise, (h) storing the set of output vectors wₖ(i).

The incremental and diffusion LMS algorithms are very effective in adaptive networks, such as adaptive sensor networks. However they do not have the efficiency and effectiveness of the RZA-LMS algorithm when it comes to application to estimation in sparse networks.

Thus, a least mean square method for estimation in sparse adaptive networks solving the aforementioned problems is desired.

### SUMMARY OF THE INVENTION

The least mean square method for estimation in sparse adaptive networks is based on the RZA-LMS algorithm, but uses the incremental LMS approach to provide estimation for each node in the adaptive network, and a step-size at each node determined by the error calculated for each node. The least mean square method for estimation in sparse adaptive networks is given by the following steps: (a) establishing a network having N nodes, where N is an integer greater than one, and establishing a Hamiltonian cycle among the nodes such that each node k is connected to two neighboring nodes, wherein the node receives data from one of the neighboring nodes and transmits data to the other one of the neighboring nodes; (b) establishing an integer i and initially setting i=1; (c) establishing an estimate of an output vector for each node k at iteration i, ψₖ(i), and an output vector at iteration i, w(i), such that ψ₀(i)=w(i−1); (d) calculating an output of the network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer; (e) calculating an error value eₖ(i) at each node k as eₖ(i)=dₖ(i)−uₖ(i)wₖ₋₁(i); (f) calculating the estimate of the output vector wₖ(i) for each node k as:

$${ψ}_{k} ( i ) = {ψ}_{k - 1} ( i ) + {μ}_{k} {u}_{k}^{T} {e}_{k} ( i ) - ρ \frac{sgn ( {ψ}_{k - 1} ( i ) )}{1 + ɛ \vert {ψ}_{k - 1} ( i ) \vert} ,$$

where ρ and ε are unitless, positive control parameters, μₖ is a constant step size and “sgn” represents the signum (or “sign”) function; (g) if eₖ(i) is greater than a selected error threshold, then setting i=i+1 and returning to step (d); otherwise, (h) storing the set of output vectors w(i) in non-transitory computer readable memory.

In an alternative embodiment, the least mean square method for estimation in sparse adaptive networks is also based on the RZA-LMS algorithm, but uses the diffusion LMS approach to provide estimation for each node in the adaptive network, and a step-size at each node determined by the error calculated for each node. Thus, in the alternative embodiment, the least mean square method for estimation in sparse adaptive networks is given by the following steps: (a) establishing an adaptive network having N nodes, where N is an integer greater than one, and for each node k, a number of neighbors of node k is given by Nₖ, including the node k, where k is an integer between one and N; (b) establishing an integer i and initially setting i=1; (c) establishing an estimate of an output vector for each node k at iteration i, ψₖ(i), and an output vector for each node k at iteration i, wₖ(i), such that

$${ψ}_{k} ( i ) = {\sum }_{l ∈ {N}_{k}}^{ } {c}_{lk} {w}_{l} ( i - 1 ) ,$$

where cₗₖ represents a weight of the estimate shared by node l for node k; (d) calculating an output of the adaptive network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer; (e) calculating an error value eₖ(i) at each node k as eₖ(i)=dₖ(i)−uₖ(i)ψₖ(i); (f) calculating the estimate of the output vector ψₖ(i) for each node k as:

$${ψ}_{k} ( i ) = {ψ}_{k} ( i ) + {μ}_{k} {μ}_{k}^{T} {e}_{k} ( i ) - ρ \frac{sgn ( {ψ}_{k} ( i - 1 ) )}{1 + ɛ \vert {ψ}_{k} ( i - 1 ) \vert} ,$$

where ρ and ε are unitless, positive control parameters, μₖ is a constant step size and “sgn” represents the signum (or “sign”) function; (g) if eₖ(i) is greater than a selected error threshold, then setting i=i+1 and returning to step (d); otherwise, (h) storing the set of output vectors wₖ(i) in non-transitory computer readable memory.

These and other features of the present invention will become readily apparent upon further review of the following specification.

### BRIEF DESCRIPTION OF THE DRAWINGS

FIG. 1 is a block diagram of a system for implementing a least mean square method for estimation in sparse adaptive networks according to the present invention.

FIG. 2 is a graph comparing performance of the present least mean square method for estimation in sparse adaptive networks against an alternative embodiment of the least mean square method for estimation in sparse adaptive networks, a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS) for a simulated 16-tap system with varying sparsity and a signal-to-noise ratio (SNR) of 20 dB.

FIG. 3 is a graph comparing performance of the present least mean square method for estimation in sparse adaptive networks against an alternative embodiment of the least mean square method for estimation in sparse adaptive networks, a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS) for a simulated 16-tap system with varying sparsity and a signal-to-noise ratio (SNR) of 30 dB.

FIG. 4 is a graph comparing performance of the present least mean square method for estimation in sparse adaptive networks against an alternative embodiment of the least mean square method for estimation in sparse adaptive networks, a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS) for a simulated 256-tap system with varying sparsity and a signal-to-noise ratio (SNR) of 20 dB.

FIG. 5 is a graph comparing performance of the present least mean square method for estimation in sparse adaptive networks against an alternative embodiment of the least mean square method for estimation in sparse adaptive networks, a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS) for a simulated 256-tap system with varying sparsity and a signal-to-noise ratio (SNR) of 30 dB.

FIG. 6 is a graph comparing performance of the present least mean square method for estimation in sparse adaptive networks against an alternative embodiment of the least mean square method for estimation in sparse adaptive networks, a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS) for a simulated 256-tap system and a signal-to-noise ratio (SNR) of 20 dB for increasing network size.

FIG. 7 is a graph comparing performance of the present least mean square method for estimation in sparse adaptive networks against an alternative embodiment of the least mean square method for estimation in sparse adaptive networks, a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS) for a simulated 256-tap system and a signal-to-noise ratio (SNR) of 30 dB for increasing network size.

FIG. 8 is a graph comparing performance of the present least mean square method for estimation in sparse adaptive networks against an alternative embodiment of the least mean square method for estimation in sparse adaptive networks, the Diffusion Least Mean Square (DLMS) algorithm, and the Incremental Least Mean Square (ILMS) algorithm for a fixed noise floor of −30 dB to check the network size required to achieve this noise floor as the signal-to-noise ratio (SNR) value increases.

Similar reference characters denote corresponding features consistently throughout the attached drawings.

### DETAILED DESCRIPTION OF THE PREFERRED EMBODIMENTS

The least mean square method for estimation in sparse adaptive networks is based on the RZA-LMS algorithm, but uses the incremental LMS approach to provide estimation for each node in the adaptive network, and a step-size at each node determined by the error calculated for each node. The present incremental RZA-LMS (IRZA-LMS) method is obtained by incorporating the extra penalty term from the RZA-LMS algorithm into the incremental scheme.

The least mean square method for estimation in sparse adaptive networks is given by the following steps: (a) establishing a network having N nodes, where N is an integer greater than one, and establishing a Hamiltonian cycle among the nodes such that each node k is connected to two neighboring nodes, wherein the node receives data from one of the neighboring nodes and transmits data to the other one of the neighboring nodes; (b) establishing an integer i and initially setting i=1; (c) establishing an estimate of an output vector for each node k at iteration i, ψₖ(i), and an output vector at iteration i, w(i), such that ψ₀(i)=w(i−1); (d) calculating an output of the network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer; (e) calculating an error value eₖ(i) at each node k as eₖ(i)=dₖ(i)−uₖ(i)ωₖ₋₁(i); (f) calculating the estimate of the output vector ψₖ(i) for each node k as:

$${ψ}_{k} ( i ) = {ψ}_{k - 1} ( i ) + {μ}_{k} {μ}_{k}^{T} {e}_{k} ( i ) - ρ \frac{sgn ( {ψ}_{k - 1} ( i ) )}{1 + ɛ \vert {ψ}_{k - 1} ( i ) \vert} ,$$

where ρ and ε are unitless, positive control parameters, μₖ is a constant step size and “sgn” represents the signum (or “sign”) function; (g) if eₖ(i) is greater than a selected error threshold, then setting i=i+1 and returning to step (d); otherwise, (h) storing the set of output vectors w(i) in non-transitory computer readable memory.

In an alternative embodiment, the least mean square method for estimation in sparse adaptive networks is also based on the RZA-LMS algorithm, but uses the diffusion LMS approach to provide estimation for each node in the adaptive network, and a step-size at each node determined by the error calculated for each node. The diffusion RZA-LMS (DRZA-LMS) method is also obtained by incorporating the extra penalty term from the RZA-LMS algorithm directly into the diffusion scheme. However, it should be noted that, for the above incremental method, the estimate for node k was updated using the estimate from node (k−1). For the diffusion method, the estimate of the same node is used, but from the previous iteration.

Thus, in the alternative embodiment, the least mean square method for estimation in sparse adaptive networks is given by the following steps: (a) establishing an adaptive network having N nodes, where N is an integer greater than one, and for each node k, a number of neighbors of node k is given by Nₖ, including the node k, where k is an integer between one and N; (b) establishing an integer i and initially setting i=1; (c) establishing an estimate of an output vector for each node k at iteration i, ψₖ(i), and an output vector for each node k at iteration i, wₖ(i), such that

$${ψ}_{k} ( i ) = {\sum }_{l ∈ {N}_{k}}^{ } {c}_{lk} {w}_{l} ( i - 1 ) ,$$

where cₗₖ represents a weight of the estimate shared by node l for node k; (d) calculating an output of the adaptive network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer; (e) calculating an error value eₖ(i) at each node k as eₖ(i)=dₖ(i)−uₖ(i)ψₖ(i); (f) calculating the estimate of the output vector ψₖ(i) for each node k as:

$${ψ}_{k} ( i ) = {ψ}_{k} ( i ) + {μ}_{k} {μ}_{k}^{T} {e}_{k} ( i ) - ρ \frac{sgn ( {ψ}_{k} ( i - 1 ) )}{1 + ɛ \vert {ψ}_{k} ( i - 1 ) \vert} ,$$

where ρ and ε are unitless, positive control parameters, μₖ is a constant step size and “sgn” represents the signum (or “sign”) function; (i) if eₖ(i) is greater than a selected error threshold, then setting i=i+1 and returning to step (d); otherwise, (j) storing the set of output vectors wₖ(i) in non-transitory computer readable memory.

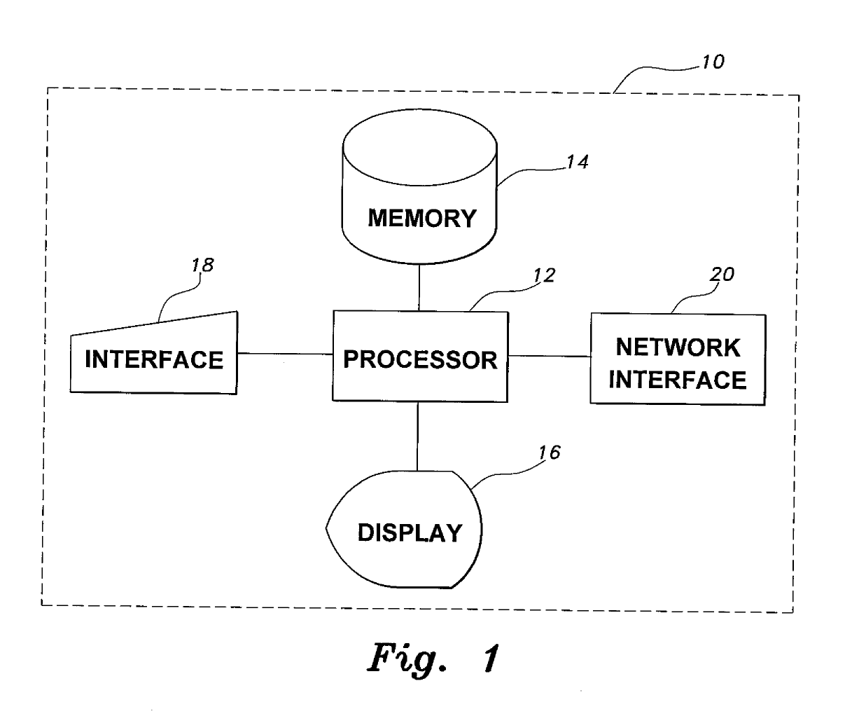

FIG. 1 illustrates a generalized system 10 for implementing the least mean square method for estimation in adaptive networks, although it should be understood that the generalized system 10 may represent a stand-alone computer, computer terminal, portable computing device, networked computer or computer terminal, or networked portable device. Data may be entered into the system 10 by the user via any suitable type of user interface 18, and may be stored in computer readable memory 14, which may be any suitable type of computer readable and programmable memory. Calculations are performed by the processor 12, which may be any suitable type of computer processor, and may be displayed to the user on the display 16, which may be any suitable type of computer display. The system 10 preferably includes a network interface 20, such as a modem or the like, allowing the computer to be networked with either a local area network or a wide area network.

The processor 12 may be associated with, or incorporated into, any suitable type of computing device, for example, a personal computer or a programmable logic controller. The display 16, the processor 12, the memory 14, the user interface 18, network interface 20 and any associated computer readable media are in communication with one another by any suitable type of data bus, as is well known in the art. Additionally, other standard components, such as a printer or the like, may interface with system 10 via any suitable type of interface.

Examples of computer readable media include non-transitory computer readable memory, a magnetic recording apparatus, an optical disk, a magneto-optical disk, and/or a semiconductor memory (for example, RAM, ROM, etc.). Examples of magnetic recording apparatus that may be used in addition to memory 14, or in place of memory 14, include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW.

In order to examine the effectiveness of both the IRZA-LMS method and the alternative DRZA-LMS method, mean and steady-state analyses for the present IRZA-LMS and DRZA-LMS methods have been performed. Considering the diffusion case first, the performance of each node will be affected by its neighbors. Thus, the whole network must be analyzed as a whole. The node equation set can be transformed into a global equation set using the following transformations:
w(i)=col {wₖ(i)}, Ψ(i)=col {Ψₖ(i)},
U(i)=diag {uₖ(i)}, D=diag {μₖI_{M}},
d(i)=col {dₖ(i)}, v(i)=col {vₖ(i)}.

The global set of equations can thus be formed as follows:

Ψ(i+1)=Gw(i), (1)

w(i+1)=Ψ(i+1)+DU^{T}(i)(d(i)−U(i)Ψ(i+1)), (2)

where G=C [symbol] I_{M}, C is an N×N weighting matrix, where {C}ₗₖ=cₗₖ, and [symbol] is the Kronecker product. The weight-error vector is then given by:

$$\begin{matrix}\tilde{w} ( i + 1 ) = w ( i + 1 ) - {w}^{( o )} \\ = ( {I}_{MN} - {DU}^{T} ( i ) U ( i ) ) Gw ( i ) + {DU}^{T} ( i ) v ( i ) - Pa ( i ) ,\end{matrix} \\ where \\ P = diag \{ {ρ}_{k} \} \\ and \\ a ( i ) = col \{ \frac{sgn ( {Ψ}_{k} ( i - 1 ) )}{1 + ɛ \vert {Ψ}_{k} ( i - 1 ) \vert} \} . \qquad ( 3 )$$

The mean of the weight-error vector is given by:

$$\begin{matrix}{o}^{‵} ( i + 1 ) = E [ \tilde{w} ( i + 1 ) ] \\ = ( {I}_{MN} - DE [ {U}^{T} ( i ) U ( i ) ] ) GE [ \tilde{w} ( i ) ] - PE [ a ( i ) ] ,\end{matrix} \qquad ( 4 )$$

and z(i)=\tilde{w}(i)−ò(i). This leads to:

z(i+1)=A(i)Gz(i)−DB(i)Gò(i)−Pp(i)+DU^{T}(i)v(i), (5)

where A(i)=(I−DU^{T}(i)U(i)), B(i)=(U^{T}(i)U(i)−E[U^{T}(i)U(i)]) and p(i)=a(i)−E[a(i)].

The mean-square deviation (MSD) is given by E└|z(i)²|┘. Solving for z(i) from equation (5), one can see that the mean-square stability depends on E[A^{T}(i)A(i)]. This expectation value has been solved for the diffusion LMS algorithm. Further, since the regressor vectors are independent of each other, the resultant matrix is block diagonal. Thus, each node can be treated separately in this case. Such a solution is already well known, and this mean-square stability analysis has now been shown to hold true for adaptive networks as well.

A similar result can also be shown for the incremental scheme. For mean-square stability, therefore, the limit for the step-size μ is defined by:

$$0 < {μ}_{k} < \frac{2}{( M + 2 ) {λ}_{k , max}} ,$$

where λ_{k,max} denotes the maximum eigenvalue for node k.

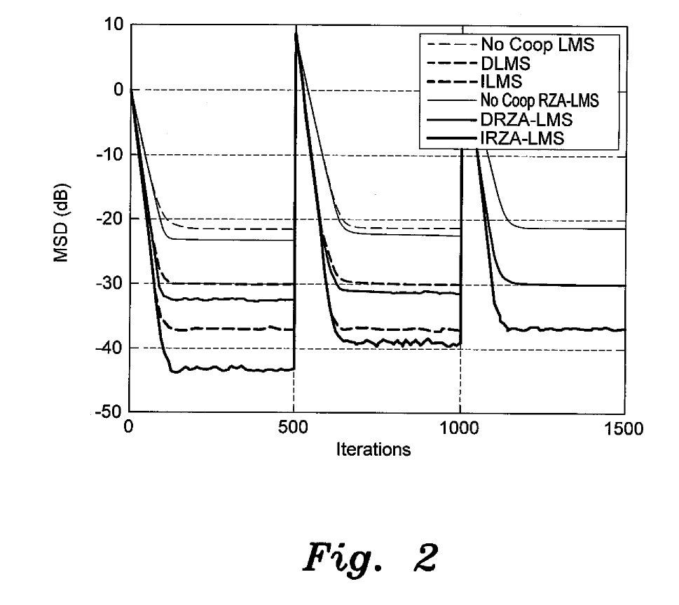

Simulations were performed in order to study the effectiveness of the present methods. In the simulations, two separate scenarios were considered. In each scenario, the present methods were compared against a non-cooperative Least Mean Square (No Coop LMS) algorithm, the Diffusion Least Mean Square (DLMS) algorithm, the Incremental Least Mean Square (ILMS) algorithm, and a non-cooperative RZA-LMS algorithm (No Coop RZA-LMS). In FIGS. 2-8, the mean square deviation (MSD) was used as the measure of performance.

In the first simulated scenario, the unknown system was represented by a 16-tap finite impulse response (FIR) filter. For the first 500 iterations, only one tap, chosen at random, was non-zero. For the next 500 iterations, all of the odd-indexed taps were set to “1”. For the last 500 iterations, the odd-indexed taps remained “1”, while the remaining taps were set to “4”. As a result, the sparsity of the unknown system varied during the estimation process. A network of 20 nodes was chosen. From the mean square stability, as given above, the step-size was determined to be less than 0.111 for this case. Thus, the step-size was set to 0.05 for the non-cooperation and diffusion cases, and 0.0025 for the incremental algorithms. Different step-sizes were set to ensure the same convergence speed.

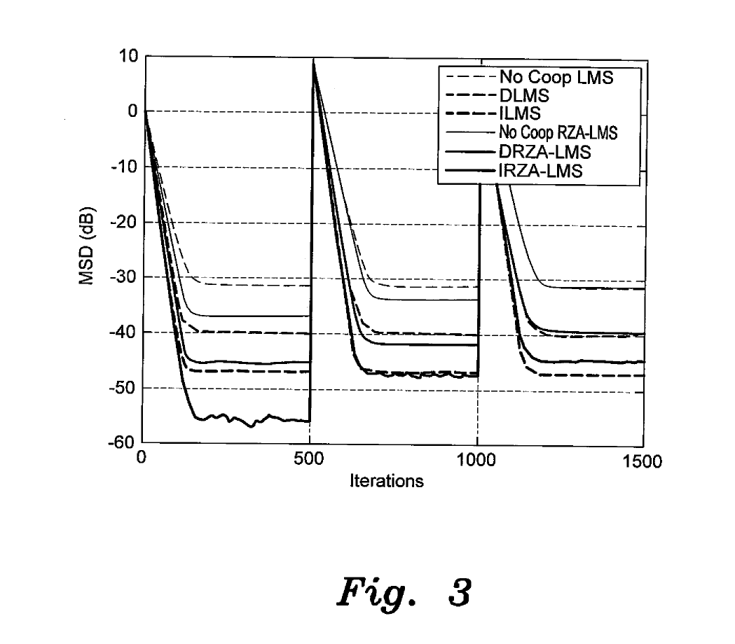

The value for Q was set to 5×10⁻⁴ and c was set to 10 for all algorithms. The results were simulated for signal-to-noise ratio (SNR) values of 20 dB and 30 dB. The results were averaged over 100 experiments. As can be seen in FIGS. 2 and 3, the incremental algorithms clearly outperform the other algorithms. The first case shows the non-cooperation case, in which all of the nodes are working independently without any data sharing. For the final 500 iterations, where all taps are non-zero, the performance of both the LMS and the RZA-LMS algorithms are similar for non-cooperation, along with the diffusion scheme and the incremental scheme when the SNR is 20 dB. However, when the SNR is 30 dB, the IRZA-LMS method outperforms all other algorithms for the first 500 iterations and the last 500 iterations. The present algorithms are found to outperform the other prior algorithms in both sparse and semi-sparse environments.

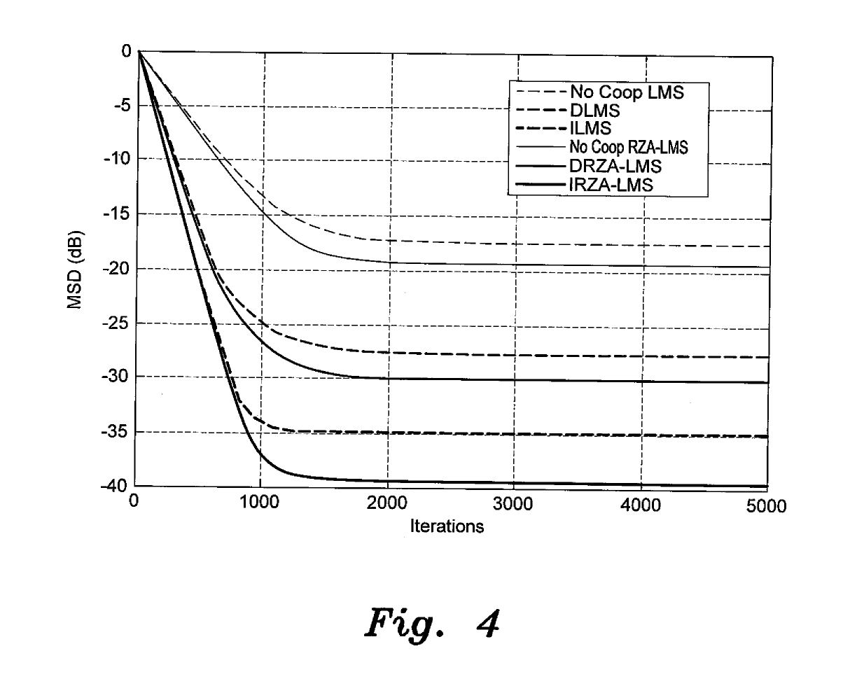

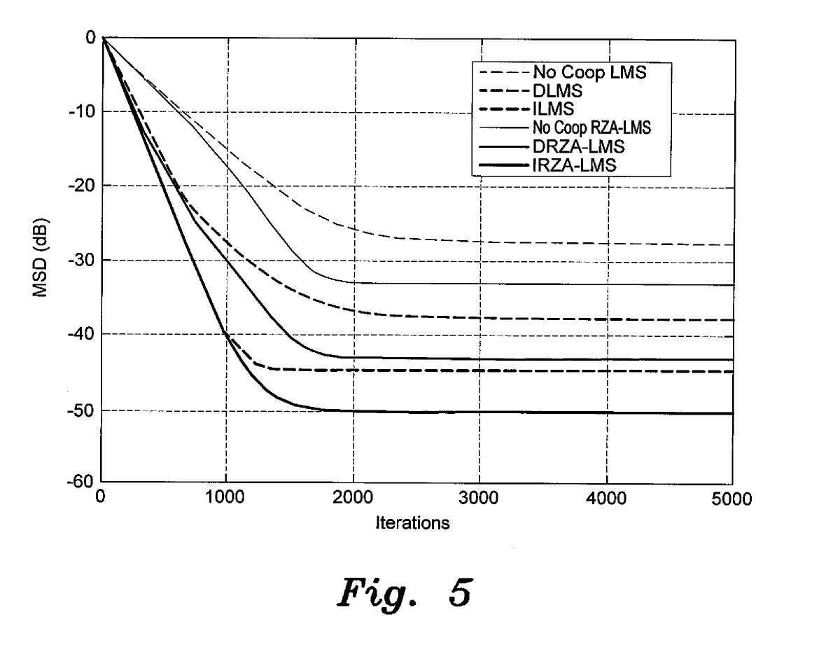

The second experimental simulation was performed with the unknown system represented by a 256-tap FIR filter, of which 16 taps, chosen randomly, were non-zero. The network size was chosen to be 20 nodes, once again. The step-size was determined to be less than 0.0078 in this scenario. Thus, the step-size was set to 5×10⁻³ for the non-cooperation and diffusion algorithms, and 2.5×10⁻⁴ for the incremental algorithms. The value for c was kept the same. The value for p was set to 1×10⁻⁵ for all algorithms. The results were averaged over 100 experiments. The results were simulated for SNR values of 20 dB and 30 dB. As shown in FIGS. 4 and 5, the RZA-LMS algorithm outperformed the LMS algorithm for all three cases. Furthermore, the DRZA-LMS algorithm performs almost exactly to the ILMS algorithm at an SNR of 30 dB, which shows its effectiveness for sparse estimation.

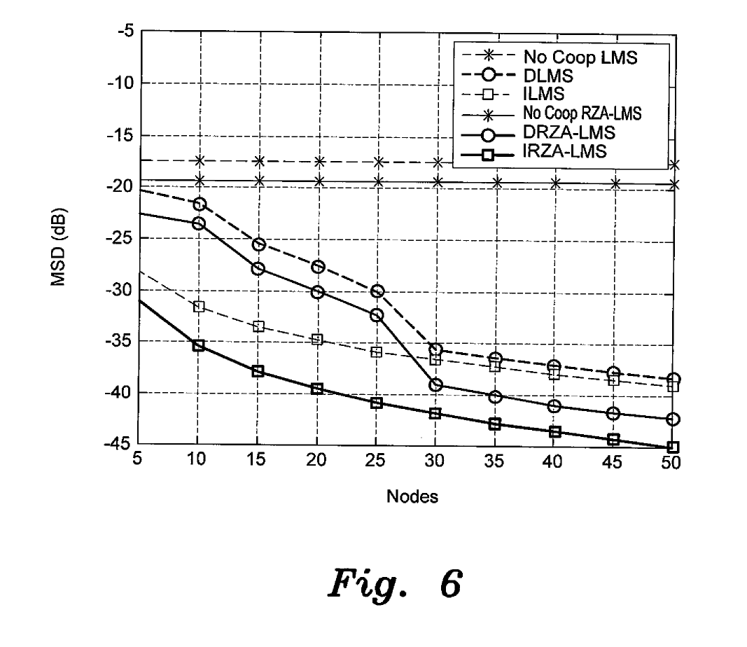

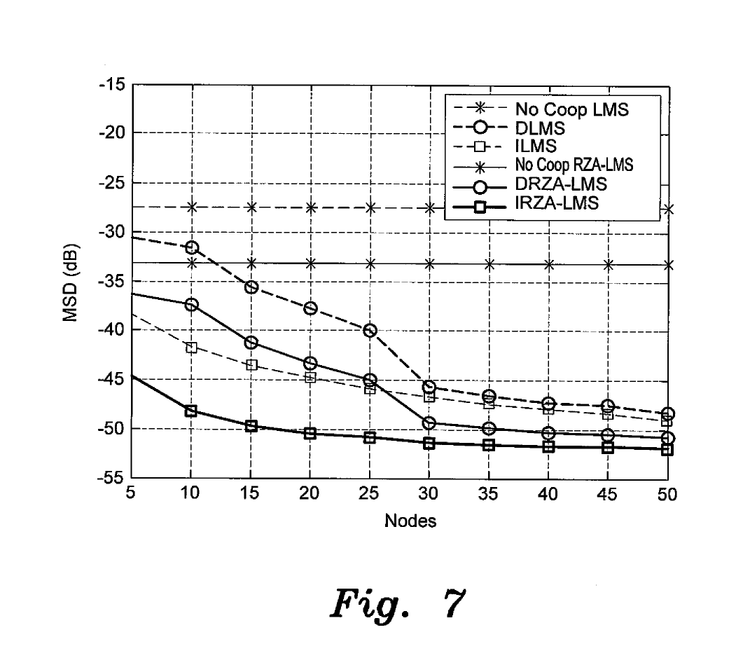

In order to study the strength of the present methods, a further experiment was performed. Using the unknown system from the second experimental simulation (i.e., the 256-tap filter), the network size was varied to see how the various algorithms would perform at steady-state. Results were simulated for SNR values of 20 dB and 30 dB. The results are shown in FIGS. 6 and 7. As can be seen in FIG. 6, the non-cooperation algorithms both have the exact same performance, even if the network has 50 nodes. The diffusion and incremental algorithms are both better than the non-cooperation case and improve steadily as the network size increases. However, once the network size exceeds 25 nodes, the DRZA-LMS algorithm outperforms both LMS algorithms. The results in FIG. 7 further illustrate the superiority of the present methods. The DLMS algorithm requires more than 10 nodes to improve upon the non-cooperation case of the RZA-LMS algorithm. Moreover, the DRZA-LMS algorithm again outperforms the ILMS algorithm once the network size exceeds 25 nodes.

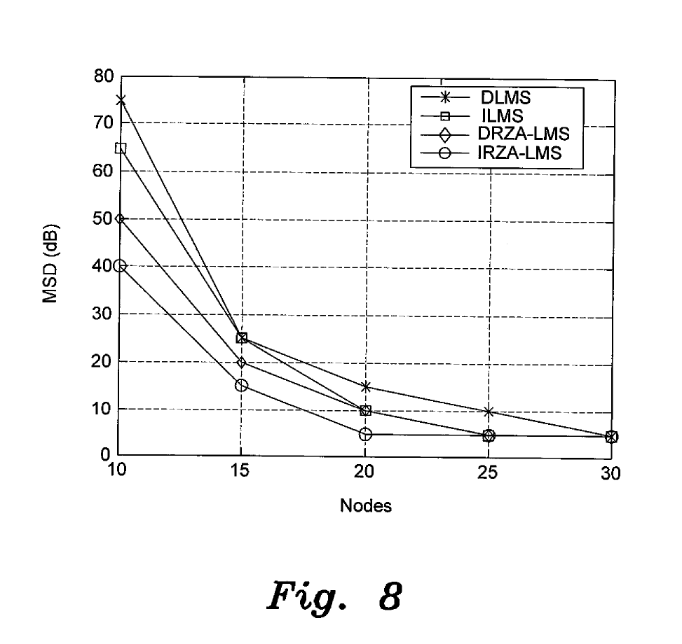

Another similar experiment was performed to test the strength in performance of the present methods. The steady-state MSD value was fixed at −30 dB. The SNR value was varied from 10 dB to 30 dB in steps of 5 dB. For each algorithm, the size of the network was increased until the steady-state MSD became equal to or less than −30 dB. As can be seen in FIG. 8, the IRZA-LMS algorithm outperforms all other algorithms and requires only 5 nodes at an SNR of 20 dB to reach the required error floor. The DRZA-LMS algorithm performs better than the ILMS algorithm initially, but they both reach the error floor of −30 dB with 5 nodes at an SNR of 25 dB. The DLMS algorithm performs the worst among all algorithms. The non-cooperation case has not been shown here because the performance of the non-cooperation case does not improve with an increase in the network size.

It is to be understood that the present invention is not limited to the embodiments described above, but encompasses any and all embodiments within the scope of the following claims.

We claim:

1. A least mean square method for estimation in sparse adaptive networks, comprising the steps of:
(a) establishing a network having N nodes, where N is an integer greater than one, and establishing a Hamiltonian cycle among the nodes such that each node k is connected to two neighboring nodes, wherein the node receives data from one of the neighboring nodes and transmits data to the other one of the neighboring nodes;
(b) establishing an integer i and initially setting i=1;
(c) establishing an estimate of an output vector for each node k at iteration i, ψₖ(i), and an output vector at iteration i, w(i), such that ψ₀(i)=w(i−1);
(d) calculating an output of the network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer;
(e) calculating an error value eₖ(i) at each node k as eₖ(i)=dₖ(i)−uₖ(i)ψₖ₋₁(i);
(f) calculating the estimate of the output vector ψₖ(i) for each node k as:
$${ψ}_{k} ( i ) = {ψ}_{k - 1} ( i ) + {μ}_{k} {μ}_{k}^{T} {e}_{k} ( i ) - ρ \frac{sgn ( {ψ}_{k - 1} ( i ) )}{1 + ɛ \vert {ψ}_{k - 1} ( i ) \vert} ,$$
where ρ and ε are unitless, positive control parameters, and μₖ represents a constant step size;
(g) if eₖ (i) is greater than a selected error threshold, then setting i=i+1 and returning to step (d), otherwise storing the set of output vectors w(i) in non-transitory computer readable memory.

2. A least mean square method for estimation in sparse adaptive networks, comprising the steps of:
(a) establishing an adaptive network having N nodes, where N is an integer greater than one, and for each node k, a number of neighbors of node k is given by Nₖ, including the node k, where k is an integer between one and N;
(b) establishing an integer i and initially setting i=1;
(c) establishing an estimate of an output vector for each node k at iteration i, ψₖ(i), and an output vector for each node k at iteration i, wₖ(i), such that
$${ψ}_{k} ( i ) = {\sum }_{l ∈ {N}_{k}}^{ } {c}_{lk} {w}_{l} ( i - 1 ) ,$$
where cₗₖ represents a weight of the estimate shared by node l for node k;
(d) calculating an output of the adaptive network at each node k as dₖ(i)=uₖ(i)w⁰+vₖ(i), where uₖ(i) represents a known regressor row vector of length M, w⁰ represents an unknown column vector of length M and vₖ(i) represents noise in the adaptive network, where M is an integer;
(e) calculating an error value eₖ(i) at each node k as eₖ(i)=dₖ(i)−uₖ(i)ψₖ(i);
(f) calculating the estimate of the output vector ψₖ(i) for each node k as:
$${ψ}_{k} ( i ) = {ψ}_{k} ( i ) + {μ}_{k} {μ}_{k}^{T} {e}_{k} ( i ) - ρ \frac{sgn ( {ψ}_{k} ( i - 1 ) )}{1 + ɛ \vert {ψ}_{k} ( i - 1 ) \vert} ,$$
where ρ and ε are unitless, positive control parameters, and μₖ represents a constant step size;
(g) if eₖ(i) is greater than a selected error threshold, then setting i=i+1 and returning to step (d), otherwise storing the set of output vectors wₖ(i) in non-transitory computer readable memory.
